(19) United States
(12) Patent Application Publication
(10) Pub. No.: US 2026/0231584 A1
(43) Pub. Date: Aug. 6, 2026

(54) MICRO-DISPLAY PANEL AND METHOD FOR MANUFACTURING THE SAME AND PIXELATED PROJECTION LAMP

(71) Applicant: Hue Inc., Shanghai (CN)

(72) Inventors: Xiaolin Wang, Shanghai (CN); Zhangying Zhou, Shanghai (CN); Chenchao Xu, Shanghai (CN)

(73) Assignee: Hue Inc., Shanghai (CN)

(21) Appl. No.: 19/457,165

(22) Filed: Jan. 23, 2026

(30) Foreign Application Priority Data
Jan. 24, 2025 (CN) 202510115792.5

(51) Int. Cl. H10H 29/851; H10H 29/01; H10H 29/49; H10H 29/85; H10H 29/853; H10H 29/855

(52) U.S. Cl. CPC H10H 29/8514; H10H 29/011; H10H 29/036; H10H 29/0361; H10H 29/0362; H10H 29/0364; H10H 29/8506; H10H 29/8511; H10H 29/853; H10H 29/855; H10H 29/857; H10H 29/49

(57) ABSTRACT

Disclosed is a micro-display panel, which includes a substrate, a micro-LED display chip, a fluorescent layer, and a package layer. The micro-LED display chip is located on the substrate, and the edge of the micro-LED display chip has metal pads, and the metal pads are electrically connected with the area of the substrate that is not covered by the micro-LED display chip, and the fluorescent layer is located on the surface of the micro-LED display chip, and the package layer covers the exposed area of the substrate and the area where the micro-LED display chip is electrically connected with the substrate.

### CROSS-REFERENCE TO RELATED APPLICATION

This application claims the priority benefit of Chinese patent application No. 202510115792.5, filed on Jan. 24, 2025. The entirety of the above-mentioned patent application is hereby incorporated by reference herein and made a part of this specification.

### BACKGROUND

### Technical Field

The present disclosure relates to the field of micro-LED technology, particularly relates to a micro-display panel and a method for manufacturing the same, and a pixelated projection lamp.

### Description of Related Art

Micro light emitting diode (Micro-LED) is a new type LED structure obtained by thin-filming, miniaturizing, and arraying the original LED structure, which integrates the arrayed micro level micro-LEDs on an active addressing drive panel to achieve the lighting and individual control of the micro-LEDs, thereby outputting the desired display image. Micro-LED can achieve pixel-level precision control, meanwhile, it has high photoelectric conversion efficiency, excellent brightness and contrast, and rapid response times, and consequently, it has been applied in the field of automotive display and lighting.

In pixelated projection lamps such as pixelated headlights, etc., white light is typically required to be emitted, while the micro-LED chip itself can only emit monochromatic light, consequently, it is often necessary to arrange fluorescent materials on the surface of the micro-LED chip to convert the monochromatic such as blue light, etc., emitted by the micro-LED into white light. Meanwhile, as mentioned earlier, the compactness requirement for pixelated projection lamp packaging is high, and the more compact the packaging, the higher the precision of pixelated control. Consequently, how to accurately arrange fluorescent materials on the surface of micro-LED chip while avoiding peripheral structures from covering the fluorescent layer and/or light-emitting area is a critical technical challenge requiring urgent resolution in the research and development of the pixelated projection lamps.

### SUMMARY

Aiming at some or all of the problems in the prior art, the first aspect of the present disclosure provides a micro-display panel, which includes:
a substrate;
a micro-LED display chip disposed on the substrate, where a plurality of metal pads are disposed at an edge of the micro-LED display chip, and are electrically connected with an area of the substrate that is not covered by the micro-LED display chip;
a fluorescent layer disposed on a surface of the micro-LED display chip; and
a package layer covering an exposed area of the substrate and an area where the micro-LED display chip is electrically connected with the substrate.

Furthermore, a dam is arranged on the surface of the micro-LED display chip around the sidewall of the fluorescent layer.

Furthermore, the micro-LED display chip has a light-emitting area, and the fluorescent layer is located on the surface of the light-emitting area, and the dam is located on the surface of the micro-LED display chip outside the light-emitting area.

Furthermore, the top of the dam is higher than the top of the fluorescent layer.

Furthermore, the outer edge of the dam does not extend beyond the edge of the micro-LED display chip.

Furthermore, the material of the dam includes silicone and/or resin.

Furthermore, the dam further includes a colored material doped in the silicone and/or resin, such that the dam is non-transparent in color, so as to position and protect the light-emitting area.

Furthermore, the colored material includes titanium dioxide and/or zirconium dioxide, or carbon black.

Furthermore, the metal pads are electrically connected with the surface of the substrate that is not covered by the micro-LED display chip, through metal bonding wires.

Furthermore, the top of the dam is not lower than the highest point of the metal bonding wires.

Furthermore, the package layer covers the area between the outer sidewall of the dam and the outer sidewall of the substrate.

Furthermore, the surface of the package layer includes at least one protrusion.

Furthermore, the material of the package layer includes silicone and/or resin.

Furthermore, a transparent cover layer is disposed on the package layer, the transparent cover layer covering the package layer.

Furthermore, the transparent cover layer further covers the surface of the fluorescent layer.

Furthermore, the top of the transparent cover layer is higher than the top of the dam, and the top of the transparent cover layer is flat.

Furthermore, the top of the transparent cover layer has a rough structure.

Furthermore, the material of the transparent cover layer includes silicone and/or resin.

Furthermore, the transparent cover layer further includes a diffusion agent and/or a surface roughening agent doped in the silicone and/or resin.

Furthermore, the bottom of the substrate further has external connection solder pads, and the upper surface of the substrate has upper metal pads, where the upper metal pads are electrically connected with the metal pads of the micro-LED display chip.

Furthermore, the material of the substrate includes ceramic and metal.

Furthermore, the substrate includes at least one circuit structure layer, and the circuit structure layer is electrically connected with the micro-LED display chip and electrically connected with external modules through the external connection solder pads.

Furthermore, the micro-LED display chip is adhered to the surface of the substrate.

Furthermore, the micro-LED display chip is adhered on the surface of the substrate through silver glue or silicone.

Furthermore, the micro-LED display chip includes a drive backplane and a micro-LED array, and the micro-LED array is arranged on the surface of the drive backplane.

Furthermore, the micro-LED array includes a plurality of light-emitting mesas.

Furthermore, the micro-LED array further includes a passivation layer, and the passivation layer covers the side surface of the light-emitting mesas.

Furthermore, the passivation layer further covers the top edge of the light-emitting mesas.

Furthermore, the micro-LED array further includes a top conductive layer, and the top conductive layer is arranged above the micro-LED array and is in contact with and covers the top of each light-emitting mesa.

Furthermore, top electrodes are arranged between adjacent light-emitting mesas, and each top electrode is interconnected.

Furthermore, the top electrodes are ring-shaped reflective electrodes, arranged around the light-emitting mesas.

Furthermore, the micro-LED display chip further includes a microlens array, and the microlens array is located above the micro-LED array area and includes a plurality of microlenses, the microlenses correspond one-to-one with the light-emitting mesas.

Furthermore, the material of the fluorescent layer includes silicone and/or resin, and the fluorescent layer further includes fluorescent powder doped in the silicone and/or resin.

Furthermore, the fluorescent layer further includes a diffusion agent and an anti-settling agent.

Furthermore, the diffusion agent includes: inorganic light diffusion agents such as nano-barium sulfate, calcium carbonate, silicon dioxide, etc., or organic nano-microbead light diffusion agent.

Furthermore, the anti-settling agent includes organic polymer compounds such as polycarboxylate or polyvinyl alcohol, etc.

Furthermore, the thickness of the fluorescent layer is greater than the particle size of the fluorescent powder.

Furthermore, the particle size of the fluorescent powder is 1 to 5 micrometers, and the thickness of the fluorescent layer is 10 to 50 micrometers.

The second aspect of the present disclosure provides a manufacturing method for the aforementioned micro-display panel, which includes:
providing a micro-LED display chip;
forming a dam around the light-emitting area of the micro-LED display chip;
forming a package layer around the micro-LED display chip and the dam; and
forming a fluorescent layer on the surface of the light-emitting area.

The third aspect of the present disclosure provides another method for manufacturing the aforementioned micro-display panel, which includes:
providing a micro-LED display chip;
forming a dam around the light-emitting area of the micro-LED display chip;
forming a fluorescent layer on the surface of the light-emitting area; and
forming a package layer around the micro-LED display chip and the dam.

Furthermore, the manufacturing method further includes:
before forming the dam, fixing the micro-LED display chip on a substrate and electrically connecting the micro-LED display chip with the substrate through metal bonding wires, where the metal bonding wires are covered in the package layer.

Furthermore, the micro-LED display chip is fixed on the substrate through a high-pressure and high-temperature bonding or a SMT mounting process.

Furthermore, the dam is a silicone film bonded on the surface of the micro-LED display chip.

Furthermore, the dam is formed by a silicone injection molding process.

Furthermore, the package layer covers at least the metal bonding wires.

Furthermore, the package layer is formed by a silicone injection molding process.

Furthermore, forming a fluorescent layer on the surface of the light-emitting area includes the steps of:
adding a fluorescent powder, a diffusion agent, and an anti-settling agent into liquid silicone or resin and stirring to form a fluorescent glue;
placing a baffle on the surface of the micro-LED display chip, where the baffle includes through-holes, and the through-holes are aligned with the light-emitting area; and
applying the fluorescent glue uniformly onto the surface of the light-emitting area through dispensing process.

Furthermore, the manufacturing method further includes:
forming a transparent cover layer on the surface of the micro-LED display chip.

The fourth aspect of the present disclosure provides a pixelated projection lamp, which includes the aforementioned micro-display panel.

In the micro-display panel and the manufacturing method for forming the same provided by the present disclosure, on the one hand, it adopts a fluorescent glue structure instead of traditional phosphors, which further reduces the overall volume of the package structure, on the other hand, a dam is arranged around the fluorescent layer to effectively prevent the peripheral adhesive from flowing into the light-emitting area and the fluorescent layer and shielding the fluorescent layer, which improves the light extraction efficiency. Meanwhile, the dam can also serve as a marker, facilitating identification and positioning of the light-emitting area during subsequent processes or client-side assembly.

### BRIEF DESCRIPTION OF THE DRAWINGS

To further explain the above and other advantages and features of various embodiments of the present disclosure, a more specific description of various embodiments of the present disclosure will be provided with reference to the accompanying drawings. It can be appreciated that these accompanying drawings depict only typical embodiments of the present disclosure, and therefore will not be construed as limiting their scope. In the accompanying drawings, identical or corresponding parts will be indicated by the same or similar reference numerals for the sake of clarity.

FIG. 1 illustrates a structural schematic diagram of a micro-display panel according to an embodiment of the present disclosure.

FIG. 2 illustrates a structural schematic diagram of a micro-LED display chip according to an embodiment of the present disclosure.

FIG. 3 illustrates a structural schematic diagram of a micro-display panel according to another embodiment of the present disclosure.

FIG. 4 illustrates a structural schematic diagram of a micro-display panel according to yet another embodiment of the present disclosure.

FIG. 5 illustrates a flowchart schematic diagram of a manufacturing method for a micro-display panel according to an embodiment of the present disclosure.

FIGS. 6A to 6F illustrate process flow schematic diagrams of a manufacturing method for a micro-display panel according to an embodiment of the present disclosure.

FIG. 7 illustrates a flowchart schematic diagram of a manufacturing method for a micro-display panel according to another embodiment of the present disclosure.

FIGS. 8A to 8F illustrate process flow schematic diagrams of a manufacturing method for a micro-display panel according to another embodiment of the present disclosure.

### DESCRIPTION OF THE EMBODIMENTS

In the following description, the present disclosure is described with reference to various embodiments. However, those skilled in the art will recognize that various embodiments can be implemented without one or more specific details or with other alternative and/or additional methods, materials, or components. In other situations, well-known structures, materials, or operations are not shown or described in detail so as not to obscure the inventive point of the present disclosure. Similarly, for the purpose of explanation, specific quantities, materials, and configurations are set forth in order to provide a comprehensive understanding of embodiments of the present disclosure. However, the present disclosure is not limited to these particular details. Furthermore, it should be appreciated that the embodiments illustrated in the accompanying drawings are illustrative representations and are not necessarily drawn to the correct scale.

In the present description, a reference to “an embodiment” or “the embodiment” means that particular feature, structure or characteristic described in connection with the embodiment are included in at least one embodiment of the present disclosure. The phrase “in one embodiment” appearing throughout this description may not necessarily all refer to the same embodiment.

It should be noted that the embodiments of the present disclosure describe the process steps in a specific order, however, this is only for the purpose of illustrating the specific embodiment, rather than limiting the order of the steps. On the contrary, in different embodiments of the present disclosure, the order of the steps can be modified according to the adjustment of the process.

In order to solve the compact package problem of high-power micro-LED pixelated projection lamp, the present disclosure uses a fluorescent glue instead of conventional phosphors, where the fluorescent glue includes fluorescent powder and a transparent adhesive with high light transmittance, such as silicone or resin, etc. Furthermore, to prevent bonding wire damage, a protective adhesive is arranged during manufacturing, and in order to prevent the protective adhesive from flowing into the light-emitting area and reducing the light-emitting area, the disclosure further arranges a dam around the light-emitting area to block adhesive of the periphery from flowing toward the central light-emitting area or the fluorescent glue during the powder spraying process.

The technical solutions of the present disclosure are further described below in conjunction with the accompanying drawings of the embodiments.

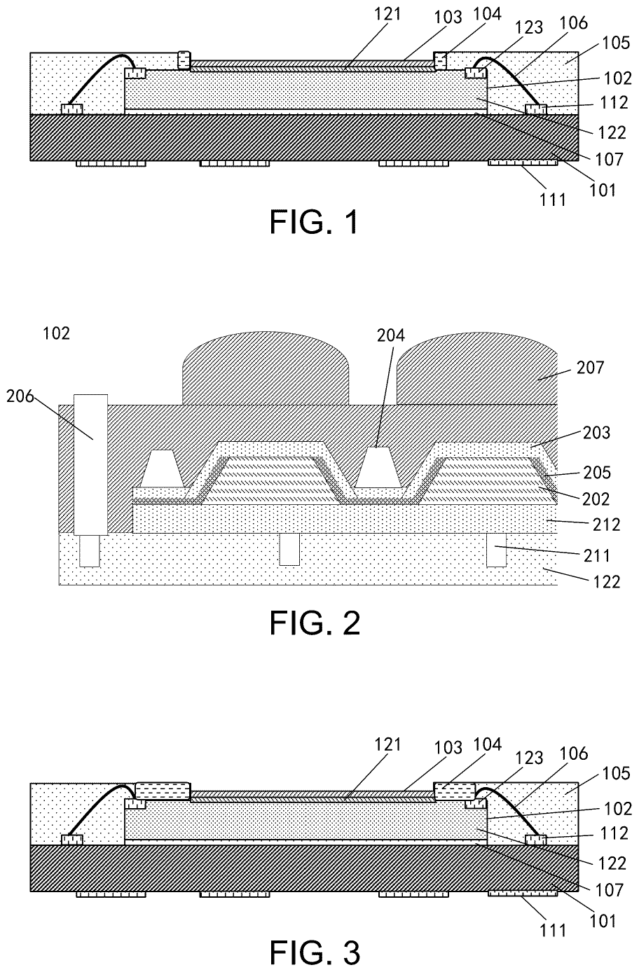

FIG. 1 illustrates a structural schematic diagram of a micro-display panel according to an embodiment of the present disclosure. As shown in FIG. 1, the micro-display panel includes a substrate 101, a micro-LED display chip 102, a fluorescent layer 103, a dam 104, and a package layer 105. The micro-LED display chip 102 is arranged on the surface of the substrate 101 and electrically connected with the substrate 101 through means such as metal bonding wires 106, etc., and the micro-LED display chip 102 includes a light-emitting area 121, and the fluorescent layer 103 is arranged on the surface of the light-emitting area 121, and the dam 104 is arranged on the surface of the micro-LED display chip outside the light-emitting area 121, and the package layer 105 is arranged on the substrate 101 and covers the exposed area of the substrate 101 and the area where the micro-LED display chip 102 is electrically connected with the substrate, and the package layer 105 completely covers at least the metal bonding wires 106, and the surface of the package layer 105 is not higher than the surface of the dam 104.

In one embodiment of the present disclosure, the material of the substrate 101 includes ceramic or metal. The substrate 101 includes at least one circuit structure layer and a plurality of external connection solder pads 111. In one embodiment of the present disclosure, the circuit structure and external connection solder pads 111 are made of metals such as copper or aluminum, etc. The circuit structure is used to achieve electrical connection of the micro-LED display chip 102 with external modules. Specifically, the metal pads of the micro-LED display chip 102 are connected to upper metal pads arranged on the first surface of the substrate 101 through the metal bonding wires 106, and the upper metal pads are further electrically connected with external connection solder pads 111 on the second surface of the substrate 101 through the multi-layer circuit structure, and are electrically connected with external modules through the external connection solder pads 111, and the external modules may, for example, be used to provide power and/or control signals, etc., to the micro-LED display chip 102.

In one embodiment of the present disclosure, the fluorescent glue package structure further includes an adhesive layer 107, i.e., the micro-LED display chip 102 is adhered on the surface of the substrate 101 through the adhesive layer 107. In one embodiment of the present disclosure, the material of the adhesive layer 107 is silver glue and/or silicone, i.e., the micro-LED display chip 102 is adhered on the surface of the substrate 101 through silver glue and/or silicone.

FIG. 2 illustrates a structural schematic diagram of a micro-LED display chip 102 according to an embodiment of the present disclosure. As shown in FIG. 2, in one embodiment of the present disclosure, the micro-LED display chip 102 includes a drive backplane 122 and a micro-LED array. The micro-LED array is bonded on the drive backplane 122 to form a light-emitting area.

As shown in FIG. 2, the micro-LEDs are bonded on the surface of the drive backplane 122 through a bottom stacked layer 212, and from bottom to top, the bottom stacked layer sequentially includes a bonding layer, a barrier layer, a reflective layer, and an adhesive layer. The bonding layer uses an AuSn alloy, and the barrier layer uses metals such as Ti or Pt, etc., to prevent alloy diffusion during melting in the bonding process, and the adhesion layer uses metals with good adhesion, such as Cr, etc., to increase adhesion between the epitaxial layer and the IC metal layer. In one embodiment of the present disclosure, the reflective layer is made of a metal with high reflectivity, such as Au or Sn, etc., to improve the reflectivity of light emitted from beneath the multi-quantum well MQW.

In some embodiments of the present disclosure, the drive backplane 122 may be electrically connected with each micro-LED in the micro-LED array through individual metal interconnections. In yet some embodiments of the present disclosure, each micro-LED may be individually electrically controlled by the drive backplane. In some embodiments of the present disclosure, the drive backplane may be electrically connected with the electrodes of the micro-LED chips through metal interconnections. In some embodiments of the present disclosure, a dielectric layer may be formed in the gaps between the micro-LEDs. In some embodiments of the present disclosure, the dielectric layer may further be formed in the gaps between the interconnections.

In one embodiment of the present disclosure, the micro-LED array includes a plurality of micro-LEDs. Each micro-LED may form at least a part of a pixel element on the micro-LED display chip. The micro-LED structures are formed in the form of an array in the micro-LED display chip, with resolutions including but not limited to 720*480, 640*480, 1920*1080, 1280*720, 2K, or 4K. The diameter of the micro-LED structures is in the nanometer-level, for example, 20 nm to 100 nm. In some embodiments of the present disclosure, the pitch of the micro-LED array, i.e., the minimum center-to-center distance between micro-LEDs may range from approximately 2 micrometers to approximately 50 micrometers. In one embodiment of the present disclosure, the number of pixels on a micro-LED chip may range from thousands to millions.

Specifically, as shown in FIG. 2, the micro-LED array includes a plurality of light-emitting mesas 202 and a continuous top conductive layer 203, and the continuous top conductive layer 203 is disposed over the micro-LED array and in contact covering with the top surface of each light-emitting mesa 202, and in electrical contact with the top surface of the light-emitting mesas to connect the top surface of each semiconductor light-emitting mesa 202(i.e., the second type epitaxial layers) in series, which is a transparent conductive layer. In one embodiment of the present disclosure, the light-emitting mesas 202 may be arranged in a regular or irregular manner on the drive panel 122 to serve as pixel points of the micro-LED display chip.

As shown in FIG. 2, the light-emitting mesa 202 includes a first type epitaxial layer, a second type epitaxial layer, and a light-emitting layer located between the first and second type epitaxial layers. In one embodiment of the present disclosure, the light-emitting mesa of each micro-LED in the micro-LED array may include a micrometer-level light-emitting mesa. In one embodiment of the present disclosure, the micrometer-level light-emitting mesa may include, from bottom to top, a first type epitaxial layer, a light-emitting layer, and a second type epitaxial layer. In other words, in the three-layer structure, the first type epitaxial layer is closest to the drive backplane; the light-emitting layer is located above the first type epitaxial layer and further away from the drive backplane; and the second type epitaxial layer is located above the light-emitting layer and furthest away from the drive backplane. In one embodiment of the present disclosure, the light-emitting layer is formed by multiple stacked quantum-well layers, particularly superlattice-stacked quantum-well layers. Preferably, the superlattice-stacked quantum-well layers include multiple pairs of quantum-well layers stacked with quantum barrier layers. In one embodiment of the present disclosure, the first type epitaxial layer is a semiconductor material having a first conductivity type and includes a plurality of semiconductor layers. The primary base material of the first type epitaxial layer may be, but is not limited to, materials such as Ga, N, As, P, In, or Al, etc. Furthermore, the first type epitaxial layer may include, from top to bottom, but is not limited to, a waveguide layer, a confinement layer, a transition layer, and a window layer; furthermore, an ohmic contact layer may be formed beneath the window layer. In one embodiment of the present disclosure, the second type epitaxial layer is a semiconductor material having a second conductivity type and includes a plurality of semiconductor layers. The primary base material of the second type epitaxial layer may be, but is not limited to, materials such as Ga, N, As, P, In, or Al, etc. Furthermore, the first type epitaxial layer may include, from top to bottom, but is not limited to, a confinement layer and a waveguide layer; furthermore, in one embodiment of the present disclosure, an ohmic contact layer may be formed on the confinement layer. In one embodiment, the first conductivity type is different from the second conductivity type.

In one embodiment, the first type epitaxial layer is an N-type GaN layer or an N-type AlGaN layer, and the second type epitaxial layer is a P-type GaN layer or a P-type AlGaN layer, that is, the material of the second type epitaxial layer may be a material layer of the second conductivity type including at least two or more elements of Ga, N, As, Al, In, and P, and the material of the first type epitaxial layer may be a material layer of the first conductivity type including at least two or more elements of Ga, N, As, Al, In, and P. In one embodiment, the light-emitting layer includes a multi-quantum-well layer and an electron barrier layer, and the multi-quantum-well layer is an InGaN/GaN multi-quantum-well layer, or an InGaN/AlGaN multi-quantum-well layer, or an InGaAs/AlGaAs multi-quantum-well layer. In another embodiment, the first type epitaxial layer may also be a P-type GaN layer or a P-type AlGaN layer, and the second type epitaxial layer is an N-type GaN layer or an N-type AlGaN layer.

In one embodiment of the present disclosure, the light-emitting layer includes at least one quantum well layer. The thickness of the quantum well layer is between 20 nm and 40 nm, for example, the thickness is 30 nm. In one embodiment of the present disclosure, the material of the quantum well layer is GaInP/(AlₓGa₁₋ₓ)_{y}In_{1-y}P, where the range of x is 0.5 to 0.9, and the range of y is 0.3 to 0.5. For example, x is 0.8 and y is 0.5. In one embodiment of the present disclosure, the relationship between x and y is that x is 1 to 2 times y. In one embodiment of the present disclosure, the light-emitting layer is a multi-quantum well (MQW).

In embodiments of the present disclosure, one of the first type epitaxial layer and the second type epitaxial layer is an N-type semiconductor layer, and the other is a P-type semiconductor layer. In one embodiment of the present disclosure, the N-type semiconductor layer further includes a doped N-type contact layer and an N-type cladding layer. The doped N-type contact layer is configured to bond with the bonding layer, and the N-type cladding layer is formed on the doped N-type contact layer. The material of the N-type cladding layer is AlₓIn₁₋ₓP, where the range of x is 0.1 to 0.5, for example, x is 0.5. Furthermore, in these embodiments, the thickness of the N-type cladding layer is no greater than 350 nm, for example, the thickness of the N-type cladding layer is 320 nm. The doping concentration of the N-type cladding layer is 5e¹⁷cm⁻³ to 1e¹⁸cm⁻³. In one embodiment of the present disclosure, the N-type semiconductor layer further includes a doped N-type contact layer and an N-type cladding layer formed on the doped N-type contact layer. The doped N-type contact layer is configured to bond with the bonding layer. The material of the doped N-type contact layer is Si-doped GaN. In one embodiment of the present disclosure, the thickness of the doped N-type contact layer is 10 nm to 30 nm. In one embodiment of the present disclosure, the doping concentration of the doped N-type contact layer is 2e¹⁸cm⁻³ to 1e¹⁹cm⁻³. In one embodiment of the present disclosure, the N-type semiconductor layer further includes an N-type spacer layer formed on the N-type cladding layer. The material of the N-type spacer layer is (AlₓGa₁₋ₓ)_{y}In_{1-y}P, where the range of x is 0.5 to 0.9, and the range of y is 0.1 to 0.5. For example, x is 0.8 and y is 0.5. In one embodiment of the present disclosure, the relationship between x and y is that x is 1 to 2 times y. The thickness of the N-type spacer layer is 50 nm to 75 nm, for example 65 nm. In one embodiment of the present disclosure, the P-type semiconductor layer includes a P-type cladding layer and a doped P-type contact layer. The P-type cladding layer is formed on the light-emitting layer, and the doped P-type contact layer is formed on the P-type cladding layer.

In one embodiment of the present disclosure, the material of the P-type cladding layer is AlₓIn₁₋ₓP, where x is 0.3 to 0.5, for example, x is 0.5. In such embodiments, the thickness of the P-type cladding layer is no greater than 380 nm, for example, the thickness of the P-type cladding layer is 360 nm.

In one embodiment of the present disclosure, the material of the doped P-type contact layer is GaAs. The thickness of the doped P-type contact layer is 10 nm to 30 nm, for example 20 nm.

In one embodiment of the present disclosure, the P-type semiconductor layer further includes a P-type spacer layer formed below the P-type cladding layer, a first doped P-type transition layer formed on the P-type cladding layer, and a second doped P-type transition layer formed on the first doped P-type transition layer. In one embodiment of the present disclosure, the material of the P-type spacer layer is (AlₓGa₁₋ₓ)_{y}In_{1-y}P, where the range of x is 0.5 to 0.9, and the range of y is 0.3 to 0.5. For example, x is 0.8 and y is 0.5. In one embodiment of the present disclosure, the relationship between x and y is that x is 1 to 2 times y. The thickness of the P-type spacer layer is 50 nm to 75 nm, for example 65 nm.

In one embodiment of the present disclosure, the material of the first doped P-type transition layer is (AlₓGa₁₋ₓ)_{y}In_{1-y}P, where the range of x is 0.1 to 0.3, and the range of y is 0.3 to 0.5. For example, x is 0.17 and y is 0.5. In one embodiment of the present disclosure, the relationship between x and y is that y is 1 to 5 times x. In some implementations, the thickness of the first doped P-type transition layer is 20 nm to 40 nm, for example 30 nm.

In one embodiment of the present disclosure, the material of the second doped P-type transition layer is AlₓGa₁₋ₓAs, where the range of x is 0.5 to 0.9, for example x is 0.6. In one embodiment of the present disclosure, the thickness of the second doped P-type transition layer is 10 nm to 30 nm, for example 20 nm.

In one embodiment of the present disclosure, the doping concentration of the second doped P-type transition layer is greater than the doping concentration of the first doped P-type transition layer. The doping concentration of the doped P-type contact layer is 1 to 10 times the doping concentration of the second doped P-type transition layer.

In one embodiment of the present disclosure, the doping concentration of the doped P-type contact layer is greater than the doping concentration of the second doped P-type transition layer. Furthermore, in one embodiment of the present disclosure, the doping concentration of the second doped P-type transition layer is 2 to 4 times the doping concentration of the first doped P-type transition layer.

For example, the doping concentration of the first doped P-type transition layer is greater than 1e¹⁸ cm⁻³, the doping concentration of the second doped P-type transition layer is in the range of 2e¹⁸ cm⁻³ to 4e¹⁸ cm⁻³, and the doping concentration of the doped P-type contact layer is greater than 5e¹⁸ cm⁻³.

As shown in FIG. 2, there are isolations between the pixel points formed by each light-emitting mesa 202, and a top electrode 204 is arranged at these isolations, and the top electrode 204 is arranged on the surface of the top conductive layer 203. In one embodiment of the present disclosure, the top electrode 204 is a ring-shaped reflective electrode arranged around the light-emitting mesa 202, and it is formed through magnetron sputtering or evaporation, and its material may be, for example, Al or Al alloy metal as the sidewall reflective mirror, and the electrode stacked metal may be metal materials such as Ni, Al, Ti, Ni, Pt, Au, etc. In one embodiment of the present disclosure, the top electrodes are connected with each other.

In some embodiments of the present disclosure, deep trenches are arranged at the isolations between adjacent light-emitting mesas 202, and the deep trenches pass through the micro-LED array, specifically, pass through the bottom stacked layer at the isolations, and the top electrodes 204 are arranged at the deep trenches. In one embodiment of the present disclosure, the top electrode between adjacent light-emitting mesas has at least two peaks. In some embodiments of the present disclosure, no deep trench is formed at the isolations between adjacent light-emitting mesas 202, but a passivation isolation layer and a continuous top conductive layer are directly formed, consequently, the surface of the continuous top conductive layer between adjacent light-emitting mesas 202 is a horizontal or substantially horizontal plane, on which the top electrode is formed, the morphology interface of the top electrode is trapezoidal or approximately trapezoidal, and the surface of the top electrode is not higher than the highest point of the continuous top conductive layer.

As shown in the figure, in one embodiment of the present disclosure, the micro-LED display chip further includes a passivation layer 205. The passivation layer 205 covers the surface and side surface of the light-emitting mesa 202 but exposes at least a part of the top surface of the light-emitting mesa, and the top conductive layer 203 is arranged on the surface of the passivation layer 205. In one embodiment of the present disclosure, the passivation layer 205 may be formed by depositing SiO₂ film layer by CVD or Al2O3 film layer by ALD to effectively reduce chip leakage current. In some embodiments of the present disclosure, the passivation layer covers only the side surface of the light-emitting mesa, but not covers the top surface of the light-emitting mesa, and the highest point of the passivation layer is flush with the top surface of the light-emitting mesa. In these embodiments, the continuous top conductive layer covering the top of the light-emitting mesa forms a horizontal or substantially horizontal planar surface. In some embodiments of the present disclosure, the passivation layer not only covers the side surface of the light-emitting mesa, but also covers the edge portion of the top surface of the light-emitting mesa, therefore, a protrusion exists at the edge portion of the top of the light-emitting mesa, such that the top conductive layer 203 covering the top of the light-emitting mesa similarly forms a protrusion at the edge of the top of the light-emitting mesa.

In one embodiment of the present disclosure, the drive backplane 122 includes a substrate, at least one drive circuit, and IC copper pillars 211 connected with the drive circuit, and the micro-LED array is electrically connected with the IC copper pillars 211. The substrate may be a transparent substrate, such as a glass substrate. Examples of other substrates include GaAs, GaP, InP, SiC, ZnO, and sapphire substrates. In one embodiment of the present disclosure, the substrate is approximately 700 micrometers thick. The drive circuit may include, for example, complementary metal oxide semiconductor (CMOS) devices or thin-film transistor (TFT) devices, etc. As shown in the figure, the IC copper pillars 211 include first IC copper pillars and second IC copper pillars, where the first IC copper pillars are electrically connected in one-to-one correspondence with the N-type semiconductor layer of the semiconductor light-emitting module, and the second IC copper pillars are electrically connected with the first electrode 206. The first electrode 206 may serve as, for example, external connection solder pads for the micro-LED display chip. In one embodiment of the present disclosure, the polarity of the first electrode is opposite to that of the second electrode. In one embodiment of the present disclosure, each semiconductor light-emitting module has a common first electrode. The first electrode may be, for example, a P-electrode or an anode electrode, and the second electrode is an electrode with opposite polarity to the first electrode, such as an N-electrode or a cathode electrode. In one embodiment of the present disclosure, the first and second electrodes and their connection components may be made of materials such as graphene, ITO, aluminum-doped zinc oxide (AZO), or fluorine-doped tin oxide (FTO), or any combination of the above materials. In another embodiment of the present disclosure, the first and second electrodes and their connection components may be made of non-transparent or transparent conductive materials, such as indium tin oxide (ITO).

As shown in the figure, in one embodiment of the present disclosure, the light-emitting area further includes a micro-lens array. The micro-lens array is arranged above the micro-LED array, where at least one micro-lens 207 is provided on the surface of the conductive layer at the top of the micro-LED, and the horizontal contour of the micro-lens is larger than the maximum horizontal contour of the micro-LED. The microlens primarily serves to converge and/or collimate light, for example, by adjusting parameters such as the thickness and curvature of the microlens, etc., the focal point of the microlens can be located in the light-emitting mesa of the micro-LED.

As shown in the figure, in one embodiment of the present disclosure, microlenses in the microlens array correspond one-to-one with the light-emitting mesas. In some embodiments of the present disclosure, adjacent microlenses have gaps therebetween and the bottoms of the adjacent microlenses are connected with each other. The bottom of the gap may be lower than the top of the light-emitting mesa of the micro-LED, or lower than the bottom of the light-emitting layer of the light-emitting mesa, or located above the second electrode, or located between two peaks of the second electrode. In other embodiments of the present disclosure, adjacent microlenses are fully connected, but there is a gap in the connection portion, and the bottom of the connection portion may be lower than the top of the light-emitting mesa of the micro-LED, or lower than the bottom of the light-emitting layer of the light-emitting mesa, or located above the second electrode, or located between two peaks of the second electrode. Furthermore, in one embodiment of the present disclosure, the microlens has an air gap inside.

In one embodiment of the present disclosure, the microlens may be formed through a plurality of deposition processes, in the process of forming the microlens, a SiO₂ film layer is deposited first, followed by ion etching, and the microlens is formed at positions on the surface of the passivation isolation layer corresponding to each light-emitting mesa.

Returning to FIG. 1, the drive backplane 122 further includes a non-light-emitting area, and the non-light-emitting area surrounds the light-emitting area. A plurality of metal pads 123 are provided on the non-light-emitting area. As mentioned earlier, the metal pads 123 are electrically connected with the upper metal pads 112 on the substrate 101 through metal bonding wires 106. The material of the metal bonding wires 106 may be, for example, one or more of the following materials: gold, silver, aluminum, etc.

As shown in FIG. 1, the fluorescent layer 103 fully covers the light-emitting area 121. As mentioned earlier, in one embodiment of the present disclosure, the material of the fluorescent layer 103 is a fluorescent glue, i.e., a transparent adhesive with high transmittance doped with fluorescent powder, and the transparent adhesive may be, for example, silicone and/or resin, etc. The fluorescent powder may work together with the blue light LED chip to generate white light, and the specific principle is as follows: blue light of the blue light chip is irradiated into the fluorescent powder, and a part of the blue light is absorbed by the fluorescent powder and excited to generate yellow light, green light or red light, another part of the blue light passes through the fluorescent powder, and the blue light that passes through mixes with the light excited by the fluorescent powder to generate white light. In one embodiment of the present disclosure, in order to improve the light-emitting effect, a diffusion agent and an anti-settling agent can also be added to the transparent adhesive used to prepare the fluorescent layer 103. The diffusion agent can improve the dispersion effect of optical fibers, making the distribution of light more uniform, for example, the diffusion agent can be inorganic light diffusion agents such as nano-barium sulfate, calcium carbonate, silicon dioxide, etc., or organic nano-microbead light diffusion agents, etc. The anti-settling agent can keep particles such as fluorescent powder, diffusion agent, etc., in the transparent adhesive in a suspended state and slow down precipitation. The anti-settling agent includes, for example, organic polymer compounds such as polycarboxylate or polyvinyl alcohol, etc.

In one embodiment of the present disclosure, the thickness of the fluorescent layer 103 is determined according to the particle size of the fluorescent powder. The lower the spraying thickness, the better the anti-light crosstalk effect, and the lower the spraying thickness, the smaller the particle size of the fluorescent powder is required. In one embodiment of the present disclosure, the particle size of the fluorescent powder in the fluorescent layer 103 is 2 to 5 μm, preferably around 2.5 μm, and the thickness of the fluorescent layer 103 is 10 to 15 μm, which can be formed by multiple spraying. In one embodiment of the present disclosure, the fluorescent layer 103 is formed by spraying 1 to 7 layers.

As shown in FIG. 1, the dam 104 is arranged around the light-emitting area 121. On one hand, the dam prevents adhesive from the outer periphery flowing toward the central light-emitting area 121 during the powder spraying process and blocks adhesive from the outer side flowing toward the fluorescent layer. On the other hand, the dam facilitates positioning and identification during subsequent processes or client-side assembly. In actual manufacturing process, the formation sequence of the fluorescent layer 103 and the package layer 105 may be interchanged. In a case that the fluorescent layer 103 is formed first, and the package layer 105 is formed later, if the height of the dam 104 is lower than that of the fluorescent layer 103, the adhesive used to form the package layer may not be intercepted and may flow towards the fluorescent layer when forming the package layer 105. Based on this, in one embodiment of the present disclosure, the height of the dam 104 is higher than the anticipated required height of the fluorescent layer 103. Furthermore, in some embodiments of the present disclosure, since the package layer 105 covers the entire metal bonding wires 106 and is not be higher than the dam 104, the height of the dam 104 is not be lower than the highest point of the metal bonding wire 106 to ensure that the package layer covers the metal bonding wire 106. In one embodiment of the present disclosure, the inner edge of the dam 104 is flush with the outer edge of the light-emitting area 121, while the outer edge of the dam 104 may be flush with the edge of the micro-LED display chip 102, and not extend beyond the edge of the micro-LED display chip 102. That is, the dam 104 may not cover (as shown in FIG. 1), or partially cover, or fully cover the metal pads 123 on the surface of the micro-LED display chip 102 (as shown in FIG. 3), and may also cover a part of the metal bonding wires 106. In one embodiment of the present disclosure, the dam 104 is made of a transparent adhesive with high light transmittance, such as silicone or resin, etc. In one embodiment of the present disclosure, colored materials such as white or black materials, such as titanium dioxide, zirconium dioxide, carbon black, etc., may also be doped into the transparent adhesive forming the dam 104, so that the dam 104 may have a color and may be positioned and identified in subsequent processes or customer assembly processes. In one embodiment of the present disclosure, the dam 104 may also directly use a prefabricated silicone frame, which is directly attached to the surface of the micro LED display chip 102 through a silicone film attach process (frame attach).

As shown in FIG. 1, the package layer 105 is arranged on the surface of the substrate 101, covering the exposed area of the substrate and the area where the micro-LED display chip is electrically connected with the substrate, and the package layer 105 fully covers the metal bonding wires 106. The package layer 105 is primarily used to protect the metal bonding wires 106 to prevent the metal bonding wire 106 from being damaged or deformed by external forces. The package layer 105 can also serve as a supporting structure to provide support. In order to prevent materials used in forming the package layer 105 from flowing onto the light-emitting area 121 or the fluorescent layer 103. In one embodiment of the present disclosure, the surface of the package layer 105 is not higher than the surface of the dam 104. In one embodiment of the present disclosure, the package layer 105 is made of a transparent adhesive with high light transmittance, such as silicone or resin, etc. In one embodiment of the present disclosure, colored materials such as white or black materials, such as titanium dioxide, zirconium dioxide, carbon black, etc., may also be doped into the transparent adhesive. In the dispensing process, due to the liquid characteristics, the liquid transparent adhesive itself may flow as flat as possible, but there may be slight protrusions in the center, or slight protrusions at the periphery, or slightly uneven on the surface.

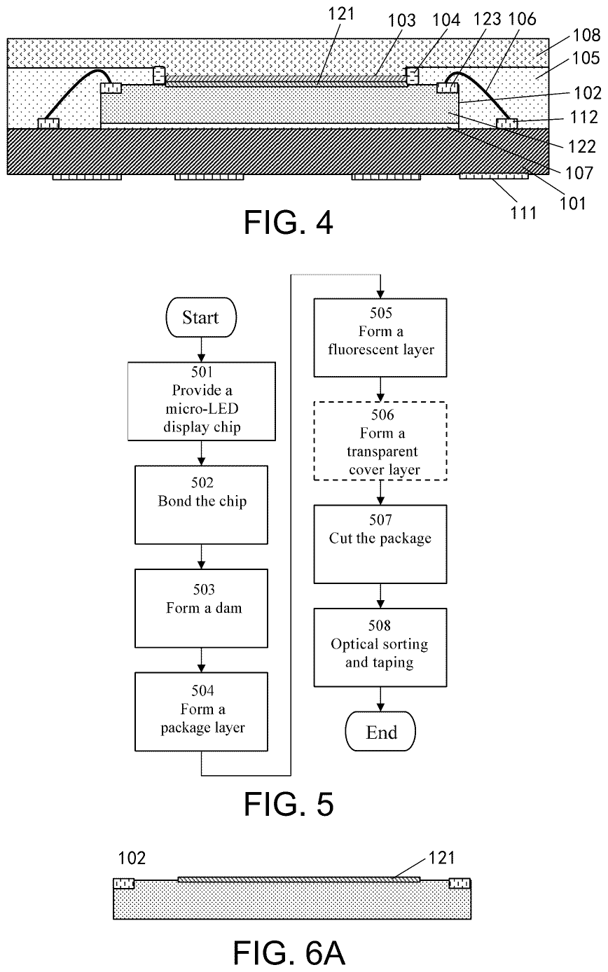

FIG. 4 illustrates a structural schematic diagram of a micro-display panel according to yet another embodiment of the present disclosure. The micro-display panel shown in FIG. 4 is substantially the same as that in FIG. 1, the difference lies in that, the micro-display panel shown in FIG. 4 further includes a transparent cover layer 108. The transparent cover layer 108 is arranged on the surfaces of the package layer, the dam, and the fluorescent layer, to protect the micro-LED of the light-emitting layer and serve as a structural support. In one embodiment of the present disclosure, the transparent cover layer 108 is made of a transparent adhesive with high light transmittance, such as silicone and/or resin, etc. In one embodiment of the present disclosure, in order to improve light extraction efficiency, materials such as diffusion agent or surface roughening agent, etc., may be doped into the transparent adhesive. The diffusion agent can improve light dispersion effect, making the distribution of light more uniform, for example, it may be inorganic light diffusion agent such as nano-barium sulfate, calcium carbonate, silicon dioxide, etc., or organic nano-microbead light diffusion agents, etc. The surface roughening agent can increase the surface roughness of the second protective layer to improve its adhesion, for example, it may include polyetheretherketone, etc.

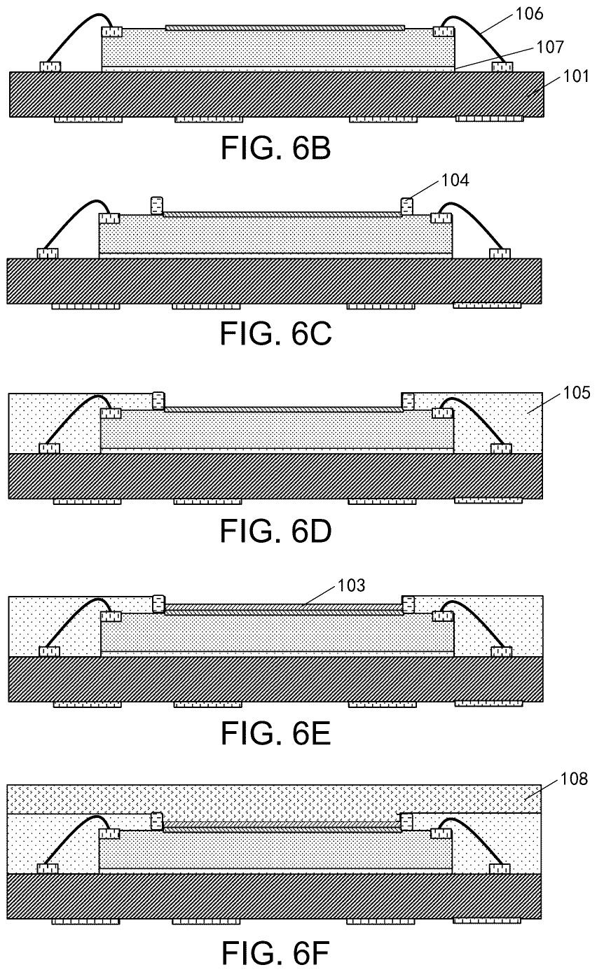

FIG. 5 illustrates a flowchart schematic diagram of a manufacturing method for a micro-display panel according to an embodiment of the present disclosure, and FIGS. 6A to 6F illustrate process flow schematic diagrams of a manufacturing method for a micro-display panel according to an embodiment of the present disclosure. As shown in the figures, a manufacturing method for a micro-display panel includes:

First, in step 501, as shown in FIG. 6A, a micro-LED display chip is provided. A metal layer, a micro-LED array, and a microlens array are formed on a drive backplane to form a micro-LED display chip 102. The micro-LED array is electrically connected with the metal layer to form the light-emitting area 121 of the micro-LED display chip. Specifically, a second type epitaxial layer, an electron barrier layer, a multi-layer quantum-well, and a first type epitaxial layer are sequentially deposited on the substrate, then the substrate is thinned to form a semiconductor light-emitting module. Meanwhile, an adhesion layer, a reflective layer, a barrier layer, and a bonding metal layer may also be sequentially deposited on the surface of the first type epitaxial layer. The semiconductor light-emitting module is then bonded to the drive backplane through the bonding metal layer, such that electrical interconnection is formed between the IC copper pillars on the drive backplane and the semiconductor light-emitting module. In one embodiment of the present disclosure, after chip bonding, the substrate may be ground and thinned to be removed, or removed by laser stripping to further thin the buffer layer structure and facilitate the subsequent formation of PN step structure. In embodiments of the present disclosure, bonding processes may use thermal compression bonding, eutectic bonding, etc. Step etching is subsequently performed, by adjusting the photolithographic morphology, the semiconductor light-emitting module is ion etched to form normally arranged trapezoid structure pixel points, in one embodiment of the present disclosure, the horizontal angles of the normally arranged trapezoid structure pixel points may be, for example, 65° to 85°. Then, a passivation isolation layer is formed on the sidewall and surface of each pixel point, in one embodiment of the present disclosure, the passivation isolation layer is formed by depositing SiO₂ film layer by CVD and/or Al₂O₃ film layer by ALD to reduce the chip leakage rate. After deposition, photolithography etching is performed above the corresponding pixel points to expose at least a part of the surface of the second type semiconductor layer. A top conductive layer is further formed on the surface of the passivation isolation layer to achieve common series connection of the second type epitaxial layers for each pixel point. Ring-shaped reflective electrode is formed at the isolations of each pixel point to serve as top electrode. In one embodiment of the present disclosure, the ring-shaped reflective electrode is formed using magnetron sputtering or evaporation processes. In one embodiment of the present disclosure, the top electrode uses Al or Al alloy metals as the sidewall reflective mirror, while the electrode stacked metals uses metal materials such as Ni, Al, Ti, Pt, or Au, etc. In one embodiment of the present disclosure, before forming the passivation isolation layer, deep trench etching may also be performed at the isolations of each pixel point, for example, using techniques such as photolithography and IBE inert gas physical etching processes, etc., and subsequently, the top electrode is formed in the deep trenches. Thereafter, the first electrode is formed on the drive backplane, and the first electrode is connected with the IC copper pillars to serve as a protective cushion and facilitate subsequent wire bonding. Finally, SiO2 is deposited and the photolithographic morphology is adjusted to form a microlens. In one embodiment of the present disclosure, the SiO2 layer, i.e., the first transmission layer, is deposited by PECVD, and the thickness of the film is approximately 2.5 to 3.5 μm, and subsequently, by adjusting the photolithographic morphology of the microlens, such as resist thickness, exposure energy, and film hardening temperature, etc., the photolithographic array morphology at the corresponding pixel points is completed, the microlens passivation protective layer SiO₂ material is ion etched to form hemispherical SiO₂ microlens with a lens-like morphology, which can improve the light output efficiency to a certain extent. At this stage, the initial structure of the micro-LED chip is formed, due to the poor step coverage of SiO2 deposited by PECVD, microcracks tend to form at the deep trenches of the pixel points, which causes the quantum-well light source to form diffuse reflection at these locations, reducing the light extraction efficiency of the microlenses, furthermore, due to the photolithography dimensions and ion etching of the microlenses, the overall microlens curvature radius, lower spacer height, sphere height, and lens sphere width are all slightly undersized and fail to achieve optimal lens conditions, therefore, in some embodiments of the present disclosure, a secondary deposition may be performed to increase the microlens curvature radius, lower spacer height, sphere height, and lens sphere width. In one embodiment of the present disclosure, the film thickness of the secondary SiO₂ deposition is determined according to the film thickness of the preceding microlens SiO₂ deposition and the microlens etching morphology, in one embodiment of the present disclosure, the secondary deposition film thickness is preferably 0.2 to 1 μm, and can be deposited in a single or multiple operations. In one embodiment of the present disclosure, the secondary SiO2 deposition uses a mixed gas of SiH4 and N₂O, and the ratio of SiH₄ to N₂O is 1:5, meanwhile, the gas flow is controlled at a low level to ensure that the deposition rate is significantly lower than that of the preceding microlens deposition, and the secondary deposition uses high-vacuum process conditions and a high flow of inert N₂ gas to further improve the step coverage effect of the secondary-deposited SiO₂, which is not prone to defects and can even repair the micro defects of the preceding microlens deposition, and a better brightness enhancement effect is obtained;

Next, in step 502, as shown in FIG. 6B, the chip is bonded. The micro-LED display chip 102 is fixed on the substrate 101, and the micro-LED display chip is electrically connected with the substrate through the metal bonding wires 106. In one embodiment of the present disclosure, the micro-LED display chip is die bonded as a whole onto the substrate, for example, the micro-LED display chip can be fixed on the substrate using processes such as high-pressure and high-temperature bonding (HBH) or SMT mounting, etc., and an adhesive layer 107 is formed between the micro-LED display chip and the substrate. After the bonding is completed, the metal pads or the first electrode on the drive backplane of the micro-LED display chip is connected with the upper metal pads on the first surface of the substrate through the metal bonding wires. It should be understood that in other embodiments of the present disclosure, the first electrode of the micro-LED display chip is provided at its bottom, and can also be directly electrically connected with the substrate without the need for metal bonding wires.

Next, in step 503, as shown in FIG. 6C, a dam is formed. A dam 104 is formed around the light-emitting area of the micro-LED display chip, and the height of the dam 104 should not be lower than the highest point of metal bonding wires 106. In one embodiment of the present disclosure, the dam 104 is made using a dispensing process, specifically, a transparent adhesive doped with colored materials is sprayed onto a designated position, i.e., the periphery of the light-emitting area through the dispensing process, and then it is cured and solidified through high-temperature baking to form the dam. In some embodiments, the colored material doped in the dam 104 may be black or white material. In order to avoid the transparent adhesive flowing toward the light-emitting area when forming the dam, in another embodiment of the present disclosure, a silicone film can also be prepared in advance and bonded to the designated position through a silicone film bonding process. In yet another embodiment of the present disclosure, the dam can also be formed by silicone injection molding. It should be understood that the dam mainly serves as a barrier, so there is no specific requirement for its width size, and it may cover a part of the metal bonding wires;

Next, in step 504, as shown in FIG. 6D, a package layer is formed. The package layer 105 is formed around the micro-LED display chip and the dam, and the package layer needs to fully cover at least the metal bonding wires. Meanwhile, in order to prevent material flow toward the light-emitting area during the formation of the package layer, the height of the package layer 105 is not higher than the height of the dam 104. In one embodiment of the present disclosure, the package layer is formed using a dispensing process, specifically, a transparent adhesive doped with colored material is sprayed onto a designated position through a dispensing process, and then it is cured and solidified through high-temperature baking to form the package layer; due to the large dispensing area and liquid characteristics, the liquid transparent adhesive itself may be as flat as possible, but there still may be slight protrusions in the center, or slight protrusions at the periphery, or slightly uneven on the surface of the package layer. In another embodiment of the present disclosure, the package layer may also be formed through silicone injection molding.

Next, in step 505, as shown in FIG. 6E, a fluorescent layer is formed. A fluorescent layer 103 is formed on the surface of the light-emitting area. In one embodiment of the present disclosure, fluorescent powder, etc., need to be first added to a liquid transparent adhesive, such as silicone or resin, etc., and it is thoroughly stirred, for example, equipment such as a mixer, etc., may be used to stir it as evenly as possible to reduce the generation of bubbles, after stirring is completed, the fluorescent glue obtained by stirring is uniformly sprayed onto the surface of the light-emitting area at normal temperature. In one embodiment of the present disclosure, in order to prevent non-light-emitting areas from being sprayed with the fluorescent glue, a baffle may be placed on the surface of the micro-LED display chip before spraying, where the baffle includes through-holes, and the through-holes are aligned with the light-emitting area. In one embodiment of the present disclosure, fluorescent powder with a particle size of 2 to 5 micrometers are used, and 1 to 7 layers are sprayed to obtain a fluorescent layer with a thickness of approximately 10 to 15 micrometers. The lower the sprayed thickness, the better the anti-light crosstalk effect, and the lower the spraying thickness, the smaller the particle size of the fluorescent powder is required. In another embodiment of the present disclosure, the fluorescent layer may also be made using a dispensing process.

Next, in step 506, as shown in FIG. 6F, a transparent cover layer is formed. A transparent cover layer 108 is formed on the surface of the micro-LED display chip to protect the light-emitting area, fluorescent layer, etc. In one embodiment of the present disclosure, the transparent cover layer is made through a molding process, specifically, a liquid adhesive is extruded into a mold cavity using a method similar to injection molding or extrusion, then cured to form the structure, where the adhesive is typically transparent, in order to improve the light extraction efficiency, materials such as diffusion agents may also be added. In another embodiment of the present disclosure, the transparent cover layer may also be formed through a dispensing process. It should be understood that in some embodiments of the present disclosure, this step may be omitted, and it proceeds directly to step 507, the package is cut;

Next, in step 507, the package is cut. The aforementioned package structure is cut into individual packages;

Finally, in step 508, the optical sorting and taping are performed. Each individual package obtained by cutting is tested, and each package is sorted according to brightness and/or wavelength and/or voltage, taping is performed based on the sorted packages.

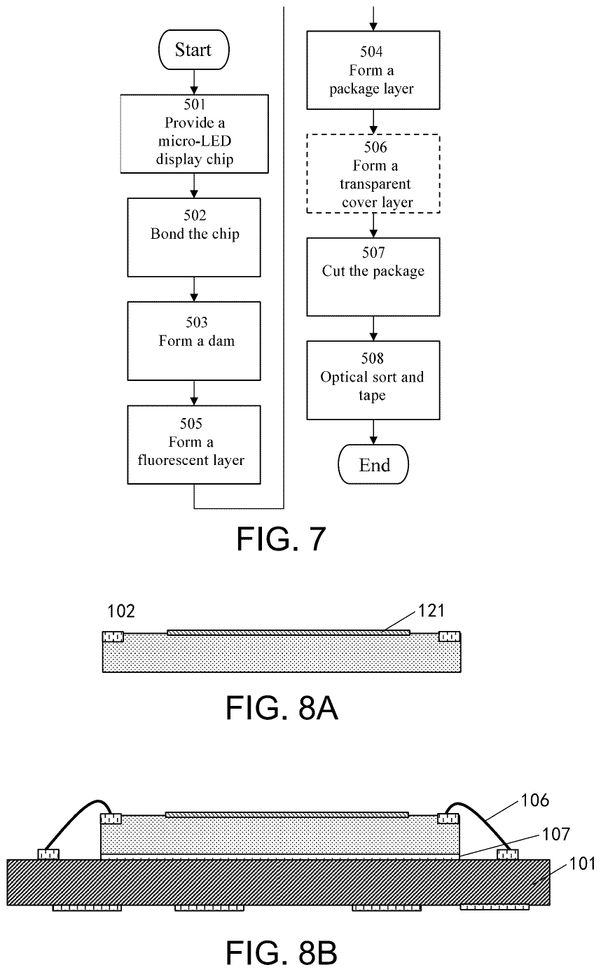

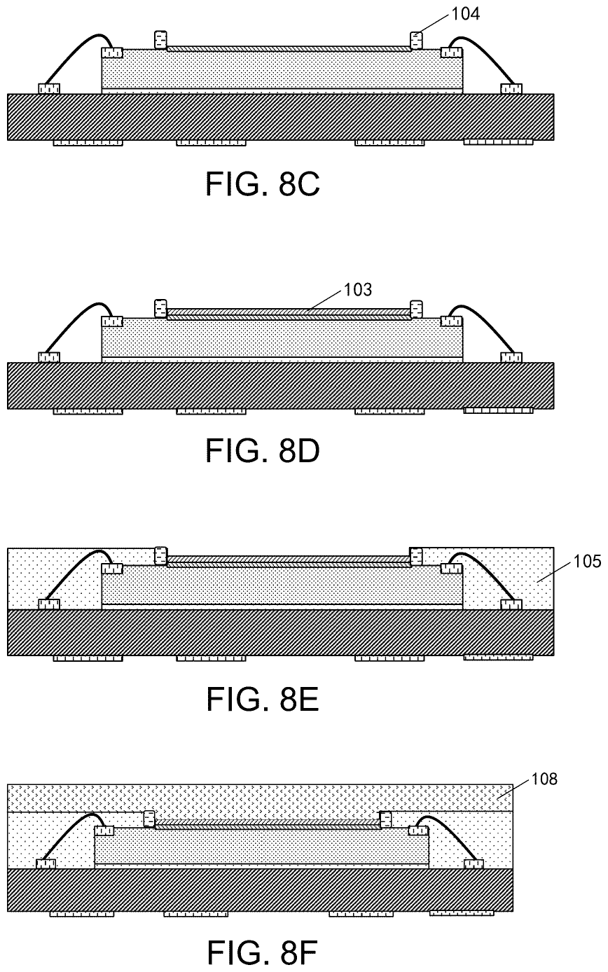

FIGS. 7 and 8A-8F illustrate the flowchart and process flow schematic diagrams of a manufacturing method for a micro-display panel according to another embodiment of the present disclosure, respectively. The manufacturing method in this embodiment is basically the same as the aforementioned embodiment, and the difference only lies in that, in the embodiment shown in FIG. 7, step 505 is performed first to form the fluorescent layer, and then step 504 is performed to form the package layer, it should be noted that, as mentioned earlier, in this manufacturing method, the height of the dam should be higher than the fluorescent layer to prevent adhesive from flowing onto the fluorescent layer during package layer formation.

The present disclosure further provides a pixelated projection lamp including the aforementioned micro-display panel.

Although the various embodiments of the present disclosure have been described above, however, it should be understood that they are presented only as examples and not as limitations. It should be apparent to those skilled in the art that various combinations, variations and changes can be made thereto without departing from the spirit and scope of the present disclosure. Therefore, the width and scope of the present disclosure disclosed herein should not be limited by the exemplary embodiments disclosed above, but should only be defined based on the accompanying claims and their equivalents.

What is claimed is:

1. A micro-display panel, comprising:
a substrate;
a micro-LED display chip disposed on the substrate, wherein a plurality of metal pads are disposed at an edge of the micro-LED display chip, and are electrically connected with an area of the substrate that is not covered by the micro-LED display chip;
a fluorescent layer disposed on a surface of the micro-LED display chip; and
a package layer covering an exposed area of the substrate and an area where the micro-LED display chip is electrically connected with the substrate.

2. The micro-display panel according to claim 1, wherein a dam is arranged on a surface of the micro-LED display chip around a sidewall of the fluorescent layer.

3. The micro-display panel according to claim 2, wherein the micro-LED display chip has a light-emitting area, the fluorescent layer is located on a surface of the light-emitting area, and the dam is located on the surface of the micro-LED display chip outside the light-emitting area.

4. The micro-display panel according to claim 2, wherein a top of the dam is higher than a top of the fluorescent layer.

5. The micro-display panel according to claim 2, wherein an outer edge of the dam does not extend beyond the edge of the micro-LED display chip.

6. The micro-display panel according to claim 2, wherein the metal pads are electrically connected with a surface of the substrate that is not covered by the micro-LED display chip through metal bonding wires.

7. The micro-display panel according to claim 6, wherein a top of the dam is not lower than a highest point of the metal bonding wires.

8. The micro-display panel according to claim 2, wherein the package layer covers an area between an outer sidewall of the dam and an outer sidewall of the substrate.

9. The micro-display panel according to claim 8, wherein a transparent cover layer is disposed on the package layer, the transparent cover layer covering the package layer.

10. The micro-display panel according to claim 9, wherein the transparent cover layer further covers a surface of the fluorescent layer.

11. The micro-display panel according to claim 9, wherein a top of the transparent cover layer is higher than a top of the dam, and the top of the transparent cover layer is flat.

12. The micro-display panel according to claim 9, wherein a top of the transparent cover layer has a rough structure.

13. A method for manufacturing a micro-display panel, comprising:
providing a micro-LED display chip;
forming a dam around a light-emitting area of the micro-LED display chip;
forming a package layer around the micro-LED display chip and the dam; and
forming a fluorescent layer on a surface of the light-emitting area.

14. The method according to claim 13, further comprising:
before forming the dam, fixing the micro-LED display chip on a substrate and electrically connecting the micro-LED display chip with the substrate through metal bonding wires, wherein the metal bonding wires are covered in the package layer.

15. The method according to claim 13, wherein forming a fluorescent layer on the surface of the light-emitting area comprises:
adding a fluorescent powder, a diffusion agent, and an anti-settling agent into liquid silicone or resin and stirring to form a fluorescent glue;
placing a baffle on the surface of the micro-LED display chip, wherein the baffle comprises through-holes, and the through-holes are aligned with the light-emitting area; and
applying the fluorescent glue uniformly onto the surface of the light-emitting area through dispensing or spraying process.

16. The method according to claim 13, wherein forming the fluorescent layer on the surface of the light-emitting area comprises:
adding a fluorescent powder, a diffusion agent, and an anti-settling agent into liquid silicone or resin and stirring to form a fluorescent glue; and
arranging the fluorescent glue on the surface of the light-emitting area through a dispensing process, and baking to cure.

17. The method according to claim 13, further comprising:
forming a transparent cover layer on surfaces of the package layer and the fluorescent layer.

18. The method according to claim 17, wherein the transparent cover layer is formed by a dispensing or silicone injection molding process.

19. The method according to claim 13, further comprising:
cutting to separate individual packages, and performing optical sorting and taping.

20. A pixelated projection lamp, comprising at least one micro-display panel according to claim 1.
